(19) United States
(12) Patent Application Publication
(10) Pub. No.: US 2017/0133588 A1
(43) Pub. Date: May 11, 2017

(54) RESISTIVE RAM CELL WITH FOCUSED ELECTRIC FIELD

(71) Applicant: HGST Netherlands B.V., Amsterdam (NL)

(72) Inventors: Daniel BEDAU, San Jose, CA (US); Jeffrey Robinson CHILDRESS, San Jose, CA (US); Oleksandr MOSENDZ, San Jose, CA (US); John C. READ, San Jose, CA (US); Derek STEWART, Livermore, CA (US)

(73) Assignee: HGST Netherlands B.V.

(21) Appl. No.: 14/935,176

(22) Filed: Nov. 6, 2015

(51) Int. Cl. H01L 45/00; H01L 27/24

(52) U.S. Cl. CPC H01L 45/1675; H01L 45/1608; H01L 45/1273; H01L 45/14; H01L 27/2463

(57) ABSTRACT

Embodiments disclosed herein generally relate to an electrode structure for a resistive random access memory (ReRAM) device cell which focuses the electric field at a center of the cell and methods for making the same. As such, a non-uniform metallic electrode may be deposited onto the ReRAM device which is subsequently exposed to an oxidation or nitrogenation process during cell fabrication. The electrode structure may be conical or pyramid shaped, and comprise at least one layer comprising a first material and a second material, wherein the concentration of the first material and the second material are varied based on location within the electrode. A metal electrode profile is formed which favors the center of the cell as the location with the greatest electric field. As such, size scaling and reliability of the non-volatile memory component are each increased.

### BACKGROUND OF THE DISCLOSURE

Field of the Disclosure

Embodiments of the present disclosure generally relate to data storage and computer memory systems, and more particularly, to resistive random access memory device structures and methods for making the same.

Description of the Related Art

An important part of any computer is a mass storage device which typically may include rotating magnetic media or a solid state media device. A number of different memory technologies exist today for storing information for use in a computing system.

In recent years there has been a demand for higher density devices, which maintain a relatively low cost per bit, for use in high capacity storage applications. Today, the memory technologies that generally dominate the computing industry are magnetic media and NAND flash; however, these memory technologies may not be able to address the current and future capacity demands of next generation computing systems.

Resistive Random Access Memory (ReRAM) is an emerging technology for next generation non-volatile memory (NVM) devices. The memory structure of a ReRAM device includes an array of cells which each carry one or multiple bits of data. The memory structure of the ReRAM device utilizes resistance values rather than an electric charge to store the data. ReRAM devices are made out of dielectric materials, the resistivity of which can be switched by the application of an electric signal. A typical ReRAM cell comprises one or multiple dielectric layers sandwiched between conductive electrodes. Some existing ReRAM cells work through a filamentary switching mechanism, and a key driver of filament formation is the electric field created by the potential difference applied to the ReRAM cell electrodes. However, controlling the filament location has been shown to be problematic. Maintaining control of the filament location is important in avoiding filament formation near device edges and, therefore, to control the device yield and switching reproducibility. Furthermore, metallic alloys of typical ReRAM devices have various susceptibility to etching and/or milling.

While the switching mechanism in other ReRAM cells may be only partially or not at all mediated by the formation of a filament, all types of ReRAM work by the action of an electric field on a dielectric, thus the need for focusing the electric field arises in any type of ReRAM.

Therefore, there is a need in art for an improved ReRAM memory cell capable of focusing the electric field at the center of the cell.

### SUMMARY OF THE DISCLOSURE

The present disclosure generally relates to an electrode structure for a resistive random access memory (ReRAM) device cell which focuses the electric field at a center of the cell and methods for making the same. As such, a non-uniform metallic electrode may be deposited onto the ReRAM device which is subsequently exposed to an oxidation or nitrogenation process during cell fabrication. The electrode structure may include at least one layer comprising a first material and a second material, wherein the concentration of the first material and the second material are varied based on location within the electrode. By a process that makes the second material more electrically insulating, a metal electrode profile is formed to favor the center of the cell as the location with the greatest electric field. This profile may be conical or pyramid shaped depending on the shape of the electrode prior to treatment. As such, size scaling and reliability of the non-volatile memory component are each increased.

In one embodiment, a resistive random access memory (ReRAM) device is disclosed. The ReRAM device includes a multilayer metallic electrode structure and a switching medium. The multilayer metallic electrode structure may include a plurality of layers. Each layer of the plurality of layers may include a first material selected from a first group and a second material selected from a second group. The first group consists of Ag, Au, Pt, Pd, Cu, Rh, or alloys or mixtures thereof. The second group consists of Mg, Ta, TaN, Si, Al, Ti, TiN, W, Hf, Nb, Zr, or alloys or mixtures thereof. A first layer of the plurality of layers closest to the switching medium may include the greatest concentration of the second material of the second group. A second layer of the plurality of layers furthest away from the switching medium may include the lowest concentration of the second material of the second group.

In another embodiment, a memory device is disclosed. The memory device may include at least one layer, a switching medium, and a contact. The layer may be located between the switching medium and the contact. At least one layer may include one of an element of a first group and one of an element of a second group. The first element is selected from the first group consisting of Ag, Au, Pt, Pd, Cu, Rh, or alloys or mixtures thereof. The second element is selected from the second group consisting of Mg, Ta, TaN, Si, Al, Ti, TiN, W, Hf, Nb, Zr, or alloys or mixtures thereof. The concentration of the element of the first group may be varied continuously and the concentration of the element of the second group may be varied continuously. The concentration of the element of the second group may be greatest near the switching medium. The concentration of the element of the first group is greatest away from the switching medium.

In yet another embodiment, a method for forming a memory device is disclosed. The method may include forming a first layer. The first layer may include a material from a first group and a material from a second group. The first group may include Ag, Au, Pt, Pd, Cu, Rh, or alloys or mixtures thereof. The second group may include Mg, Ta, TaN, Si, Al, Ti, TiN, W, Hf, Nb, Zr, or alloys or mixtures thereof. The method may further include forming a second layer. The second layer may include a material from a first group and a material from a second group. The first group may include Ag, Au, Pt, Pd, Cu, Rh, or alloys or mixtures thereof. The second group may include Mg, Ta, TaN, Si, Al, Ti, TiN, W, Hf, Nb, Zr, or alloys or mixtures thereof. The second layer may be below the first layer. The second layer may include a greater concentration of the material from the second group than the first layer. The first layer and the second layer may collectively form an electrode. The method may also include etching or ion-milling the memory device. The method may additionally include exposing the memory device to an oxygen-rich or a nitrogen-rich environment to form the layers in a conical structure. The regions of the electrode with the greatest concentration of the material from the second group contain the greatest concentration of an oxide or an insulator material.

In yet another embodiment, a method for forming a memory device is disclosed. The method may include forming a first layer, a second layer, a third layer, a fourth layer, and a fifth layer. The first layer may include a material from a first group and a material from a second group. The first group may include Ag, Au, Pt, Pd, Cu, Rh, or alloys or mixtures thereof. The second group may include Mg, Ta, TaN, Si, Al, Ti, TiN, W, Hf, Nb, Zr, or alloys or mixtures thereof. The second layer may include a material from a first group and a material from a second group. The first group may include Au, Pt, Pd, Cu, Rh, or alloys or mixtures thereof. The second group may include Mg, Ta, TaN, Si, Al, Ti, TiN, W, Hf, Nb, Zr, or alloys or mixtures thereof. The second layer may be below the first layer. The second layer may include a greater concentration of the material from the second group than the first layer. The first layer and the second layer may collectively form a first electrode. The third layer may include a material from a third group. The third group may include Mg, Ta, TaN, Si, Al, Ti, TiN, W, Hf, Nb, Zr, or alloys or mixtures thereof. The fourth layer may include a material from the first group and a material from the second group. The fifth layer may include a material from the first group and a material from the second group. The fifth layer may be below the fourth layer. The fifth layer may include a lower concentration of the material from the second group than the fourth layer. The fourth layer and the fifth layer may collectively form a second electrode. The third layer may be between the first electrode and the second electrode. The method may further include etching or ion-milling the memory device. The method may also include exposing the first electrode, the second electrode, and the third layer to an oxygen-rich or a nitrogen-rich environment to form the first electrode and the second electrode in a conical structure. Regions of the first electrode and the second electrode with the greatest concentration of the material from the second group may contain the greatest concentration of an oxide or an insulator material. The exposing may form the third layer into a switching medium.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a memory cell of a conventional resistive random access memory device.

FIG. 2A illustrates a multilayer electrode structure of a resistive random access memory device, according to one embodiment disclosed herein.

FIGS. 2B and 2C illustrate the structure of FIG. 2A after exposure to an oxygen-rich or a nitrogen-rich environment, according to at least one embodiment disclosed herein.

FIG. 2D illustrates an alternative embodiment of the structure of FIG. 2B, according to one embodiment disclosed herein.

FIG. 2E illustrates an alternative embodiment of the structure of FIG. 2D, according to one embodiment disclosed herein.

FIG. 3 illustrates operations of a method for forming a memory device, according to at least one embodiment disclosed herein.

FIGS. 4A and 4B illustrate operations of a method for forming a memory device, according to at least one embodiment disclosed herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made to embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

The present disclosure generally relates to an electrode structure for a resistive random access memory (ReRAM) device cell which focuses the electric field at a center of the cell and methods for making the same. As such, a non-uniform metallic electrode may be deposited onto the ReRAM device which is subsequently exposed to an oxidation or nitrogenation process during cell fabrication. The electrode structure may comprise at least one layer comprising a first material and a second material, wherein the concentration of the first material and the second material are varied based on location within the electrode. By a process that makes the second material more electrically insulating, a metal electrode profile is formed which favors the center of the cell as the location with the greatest electric field. This profile may be conical or pyramid shaped depending on the shape of the electrode prior to treatment. As such, size scaling and reliability of the non-volatile memory component are each increased.

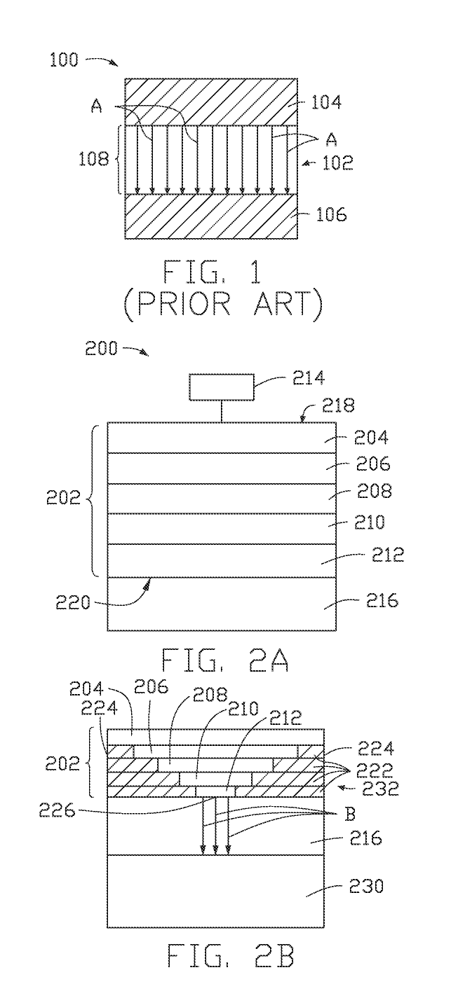

FIG. 1 illustrates a memory cell 102 of a conventional resistive random access memory (ReRAM) device 100. The ReRAM device 100 may include an upper metallic electrode 104, a lower metallic electrode 106, and a switching medium 108. The upper metallic electrode 104 may maintain a positive voltage. The lower metallic electrode 106 may maintain a negative voltage. The switching medium 108 may be an insulator material or a semiconductor material. A key driver of filament formation is the electric field, noted by reference arrows A in FIG. 1. The electric field may be created by the potential difference applied to the upper metallic electrode 104 and the lower metallic electrode 106.

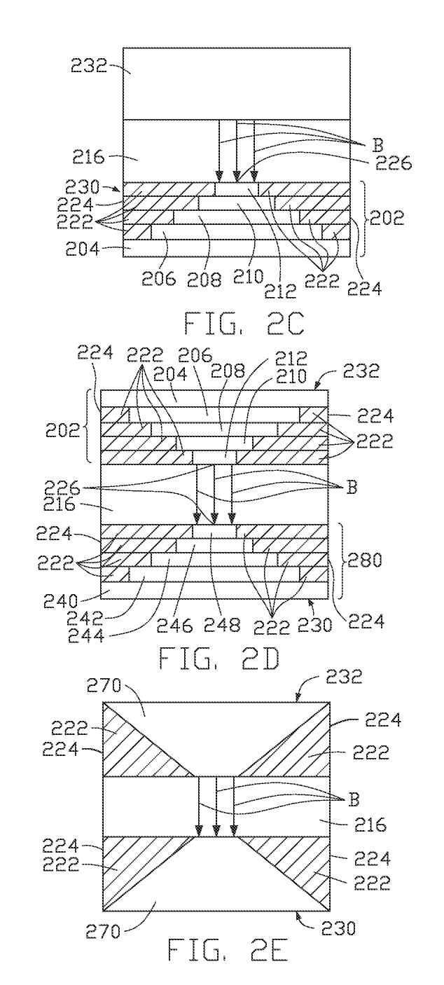

FIG. 2A illustrates a resistive random access memory (ReRAM) device 200, according to the present disclosure. The ReRAM device 200 may include a multilayer electrode structure 202 and a switching medium 216. In some embodiments, the multilayer electrode structure 202 may be a multilayer metallic electrode structure. In certain embodiments, the ReRAM device 200 may further include a contact 214. In some embodiments, the multilayer electrode structure 202 may be an upper electrode structure. The upper electrode structure may maintain a positive voltage or a negative voltage. In some embodiments, the multilayer electrode structure 202 may be a lower electrode structure. The lower electrode structure may maintain a voltage polarity opposite that of the upper electrode structure. In some embodiments, the multilayer electrode structure 202 may be an upper electrode structure and a lower electrode structure. As such, the multilayer electrode structure 202 may be sandwiched between the contact 214 and the switching medium 216. The contact 214 may be coupled to the multilayer electrode structure 202 on a first side 218 of the electrode structure 202. The switching medium 216 may be coupled to the multilayer electrode structure 202 on a second side 220 of the electrode structure 202, wherein the second side 220 is opposite the first side 218. The switching medium 216 may be coupled to the multilayer electrode structure 202 on the first side 218 of the electrode structure 202.

The multilayer electrode structure 202 may include a plurality of layers 204, 206, 208, 210, 212. Each layer of the plurality of layers 204, 206, 208, 210, 212 may be an electrode. Although five layers 204, 206, 208, 210, 212 are shown, it is contemplated that any number of layers may be utilized. In one embodiment, the plurality of layers 204, 206, 208, 210, 212 may include between about two layers and about ten layers. In another embodiment, the plurality of layer 204, 206, 208, 210, 212 may include more than ten layers. Each layer 204, 206, 208, 210, 212 may be a metallic layer. Each layer may maintain a thickness of between about 0.05 nm and about 4 nm. In some embodiments, each layer 204, 206, 208, 210, 212 of the plurality of layers may have a different thickness.

Each layer 204, 206, 208, 210, 212 of the plurality of layers may comprise a first material selected from a first group and a second material selected from a second group. The first group may consist of Ag, Au, Pt, Pd, Cu, Rh, or alloys or mixtures thereof. The second group may consist of Mg, Ta, TaN, Si, Al, Ti, TiN, W, Hf, Nb, Zr, or alloys or mixtures thereof. The second material may be made semiconducting or insulating by an oxidation or nitration process.

The layers 204, 206, 208, 210, 212 closest to the switching medium 216 may contain the greatest concentration of material from the second group. The layer 204, 206, 208, 210, 212 furthest away from the switching medium 216 may contain the lowest concentration of material from the second group. In some embodiments, the layers 204, 206, 208, 210, 212 furthest away from the switching medium 216 may contain no material from the second group. The layers 204, 206, 208, 210, 212 may contain progressively higher concentrations of material from the second group as the layers 204, 206, 208, 210, 212 become closer to the switching medium 216. As such, the composition of the material from the first group and the composition of the material from the second group within each layer may vary depending on the location of the layer 204, 206, 208, 210, 212. In some embodiments, the layer, for example layer 204, coupled to the contact 214 may contain material only from the first group. Furthermore, in some embodiments, the layer, for example layer 212, coupled to the switching medium 216 may contain only material from the second group. By way of example only, if X represents a material of the first group, Y represents a material of the second group, and B, C, D, and E represent a percentage of concentration wherein E %>D %>C %>B %, then each layer may be represented by the following equations:

X (1) (Layer 204)

X_{100-B}Y_{B} (2) (Layer 206)

X_{100-C}Y_{C} (3) (Layer 208)

X_{100-D}Y_{D} (4) (Layer 210)

X_{100-E}Y_{E} (5) (Layer 212)

The switching medium 216 may be an insulator material and/or a semiconductor material. In some embodiments, the switching medium 216 may be deposited as a metal and/or the switching medium may consist of Mg, Ta, TaN, Si, Al, Ti, TiN, W, Hf, Nb, Zr, or alloys or mixtures thereof.

The plurality of layers 204, 206, 208, 210, 212 of the ReRAM device 200 may be etched during fabrication to define the electrodes therein. In some embodiments, the plurality of layers 204, 206, 208, 210, 212 may be ion-milled to define the electrodes therein. Subsequent to the etching and/or ion-milling each layer 204, 206, 208, 210, 212 may be exposed to an oxygen-rich and/or nitrogen-rich environment, such as, for example, a gas and/or a plasma. The gas and/or plasma may oxidize and/or nitrogenize each layer 204, 206, 208, 210, 212 to a concentration which may be dependent on the concentration of the material from the second group present in each layer 204, 206, 208, 210, 212. The deposition of the plurality of layers 204, 206, 208, 210, 212 may gradually increase susceptibility to etching and/or milling at an exposed side of the layers 204, 206, 208, 210, 212.

In some embodiments, the switching medium 216 may be exposed to the oxygen-rich and/or nitrogen-rich environment at the same time as each of the layers 204, 206, 208, 210, 212. As such, in some embodiments, the switching medium may be a metallic multilayer switching medium in the ReRAM device and may be fully oxidized and/or nitrogenized. Oxidizing and/or nitrogenizing the switching medium may allow for the entire ReRAM device to be exposed to an oxygen-rich and/or a nitrogen-rich environment in a single step.

FIGS. 2B and 2C illustrate an embodiment of the ReRAM device 200 of FIG. 2A that has been exposed to an oxygen-rich and/or a nitrogen-rich environment. The ReRAM device 200 of FIG. 2B illustrates the layers 204, 206, 208, 210, 212 of the multilayer electrode structure 202 as an upper electrode 232. In the embodiment of FIG. 2B, the lower electrode 230 may not be layered. As such, the multilayer electrode structure 202 may maintain a positive voltage. In some embodiments, the multilayer electrode structure 202 may maintain a negative voltage. The lower electrode 230 may maintain a voltage polarity opposite of the upper electrode 232. The ReRAM device 200 of FIG. 2C illustrates the layers 204, 206, 208, 210, 212 of the multilayer electrode structure 202 as a lower electrode 230. In the embodiment of FIG. 2C, the upper electrode 232 may not be layered. As such, the multilayer electrode structure 202 may maintain a negative voltage. In some embodiments, the multilayer electrode structure 202 may maintain a positive voltage. The upper electrode 232 may maintain a voltage polarity opposite of the lower electrode 230.

The varying degree of oxidation, and/or nitrogenization, may create layers 204, 206, 208, 210, 212 with a cone-like or a pyramid-like metallic electrode structure within each layer 204, 206, 208, 210, 212, as shown in FIGS. 2B and 2C, with the oxide 222 or other insulator formed near an outside edge 224 of the multilayer electrode structure 202. As such, the amount of oxide 222 or other insulator on each layer 204, 206, 208, 210, 212 may vary depending on the location of the layer 204, 206, 208, 210, 212. As shown, layer 212 may have the most oxide 222 or other insulator present as it is closest to the switching medium 216. Each layer 204, 206, 208, 210, 212 may progressively have less oxide or other insulating material present thereon as the distance between the layer 204, 206, 208, 210, 212 and the switching medium 216 increases. The layers 204, 206, 208, 210, 212 featuring the cone-like or pyramid-like electrode structure may create a higher electric field, as noted by reference arrows B, near the point 226 of the cone-like or pyramid-like electrode structure when a voltage is applied. As such, the higher electric field near the point 226 may favor the formation of a filament in the vicinity of the point 226.

FIG. 2D illustrates an alternative embodiment of the ReRAM device 200 of FIGS. 2B and 2C. As shown in FIG. 2D, both the upper electrode 232 and the lower electrode 230 may each comprise the multilayer electrode structure 202 of FIGS. 2B and 2C.

The lower electrode 230 may be a second multilayer electrode structure 280, comprising a second plurality of layers 240, 242, 244, 246, 248, wherein each layer of the second plurality of layers 240, 242, 244, 246, 248 comprises a first material selected from a first group and a second material selected from a second group. The first group may consist of Ag, Au, Pt, Pd, Cu, Rh, or alloys or mixtures thereof. The second group may consist of Mg, Ta, TaN, Si, Al, Ti, TiN, W, Hf, Nb, Zr, or alloys or mixtures thereof. A first layer 248 of the second plurality of layers 240, 242, 244, 246, 248 that is closest to the switching medium 216 may comprise the greatest concentration of the second material of the second group. A second layer 240 of the second plurality of layers 240, 242, 244, 246, 248 that is furthest away from the switching medium 216 may comprise the lowest concentration of the first material of the second group.

The multilayer electrode structure 202 of the upper electrode 232 may include layers 204, 206, 208, 210, 212. The second multilayer electrode structure 280 of the lower electrode 230 may include layers 240, 242, 244, 246, 248 which may be substantially similar to the layers 204, 206, 208, 210, 212 of the multilayer electrode structure 202, however the layers 240, 242, 244, 246, 248 of the second multilayer electrode structure 280 may be a mirror image of the layers 204, 206, 208, 210, 212 of the upper electrode 232. In the embodiment shown in FIG. 2D, the layers 204, 206, 208, 210, 212 of the multilayer electrode structure 202 and the layers 240, 242, 244, 246, 248 of the second multilayer electrode structure 280 lower electrode 230 may each be exposed to an oxygen-rich and/or a nitrogen-rich environment, as described supra with reference to FIGS. 2B and 2C. As such, layer 204 may share similar properties with layer 240, such as both layer 204 and 240 may be furthest away from the switching medium 216. Layer 206 may share similar properties with layer 242, layer 208 may share similar properties with layer 244, layer 210 may share similar properties with layer 246, and layer 212 may share similar properties with layer 248 in that layers 212 and 248 may be closest to the switching medium 216.

The varying degree of oxidation, and/or nitrogenization, may create layers 204, 206, 208, 210, 212 of the multilayer electrode structure 202 of the upper electrode 232 and layers 240, 242, 244, 246, 248 of the second multilayer electrode structure 280 of the lower electrode 230 with a cone-like or a pyramid-like metallic electrode structure within each layer 204, 206, 208, 210, 212, 240, 242, 244, 246, 248 as shown in FIG. 2D, with the oxide 222 or other insulator formed near an outside edge 224 of each of the multilayer electrode structure 202 and the second multilayer electrode structure 280. As such, the amount of oxide 222 or other insulator on each layer 204, 206, 208, 210, 212, 240, 242, 244, 246, 248 may vary depending on the location of the layer 204, 206, 208, 210, 212, 240, 242, 244, 246, 248. As shown, layers 212 and 248 may have the most oxide or other insulator present as they are closest to the switching medium 216. Each layer 204, 206, 208, 210, 212, 240, 242, 244, 246, 248 may progressively have less oxide or other insulating material present thereon as the distance between the layer 204, 206, 208, 210, 212, 240, 242, 244, 246, 248 and the switching medium 216 increases. The layers 204, 206, 208, 210, 212, 240, 242, 244, 246, 248 featuring the cone-like or pyramid-like electrode structure may create a higher electric field, as noted by reference arrows B, near the points 226 of the cone-like or pyramid-like electrode structure when a voltage is applied. As such, the higher electric field near the points 226 may favor the formation of a filament in the vicinity of the points 226.

Each layer 204, 206, 208, 210, 212, 240, 242, 244, 246, 248 as shown in FIGS. 2B, 2C, and/or 2D may be deposited by thin-film co-deposition methods. As such, an alloy composition may be varied by varying the relative deposition rate of two or more elements deposited simultaneously.

FIG. 2E illustrates an alternative embodiment of the structure of FIG. 2D. As shown in FIG. 2E the multilayer electrode structure 202 for the upper electrode 232 may be replaced by a single layer 270. The second multilayer electrode structure 280 for the lower electrode 230 may be replaced by a single layer 270. The upper electrode 232, the lower electrode 230, and/or both the upper electrode 232 and the lower electrode 230 may comprise the single layer 270. The single layer may continuously vary the relative percentage of the element from the first group and the element from the second group, such that the single layer 270 is richer and/or contains the greatest concentration of the element from the second group near the switching medium 216, as discussed supra.

The single layers 270 of the ReRAM device 200 may be etched during fabrication to define the electrodes therein. In some embodiments, the single layers 270 may be ion-milled to define the electrodes therein. Subsequent to the etching and/or ion-milling the single layers 270 may be exposed to an oxygen-rich and/or nitrogen-rich environment, such as, for example, a gas and/or a plasma. The gas and/or plasma may oxidize and/or nitrogenize each single layer 270 to a concentration which may be dependent on the concentration of the material from the second group present in each single layer 270.

The ReRAM device 200 of FIG. 2E may be exposed to an oxygen-rich and/or a nitrogen-rich environment. The upper electrode 232 may maintain a positive voltage or a negative voltage. The lower electrode 230 may maintain a polarity opposite of the upper electrode 232. The varying degree of oxidation, and/or nitrogenization, may create a cone-like or a pyramid-like electrode structure in the single layers 270. As shown in FIG. 2E, the oxide 222 or other insulator may be formed near an outside edge 224 of the ReRAM device 200. As such, the amount of oxide 222 or other insulator on each single layer 270 may vary depending on the location within the single layer 270. As such, the concentration of oxide 222 or other insulator may vary. As shown, more oxide 222 or other insulator may be present in each single 270 as the layer becomes closer to the switching medium 216. Furthermore, a higher electric field, as noted by reference arrows B, near point 226 of the cone-like or pyramid-like electrode structure may be present, such that the electric field is focused. As such, the higher electric field near the point 226 may favor the formation of a filament in the vicinity of the point 226.

As compared to the electric field of FIG. 1, noted by reference arrows A, the electric field of FIGS. 2B, 2C, 2D, and 2E noted by reference arrows B, is narrowed. Reference arrows B show that the electric field of FIGS. 2B, 2C, 2D, and 2E is focused toward the center of the cell.

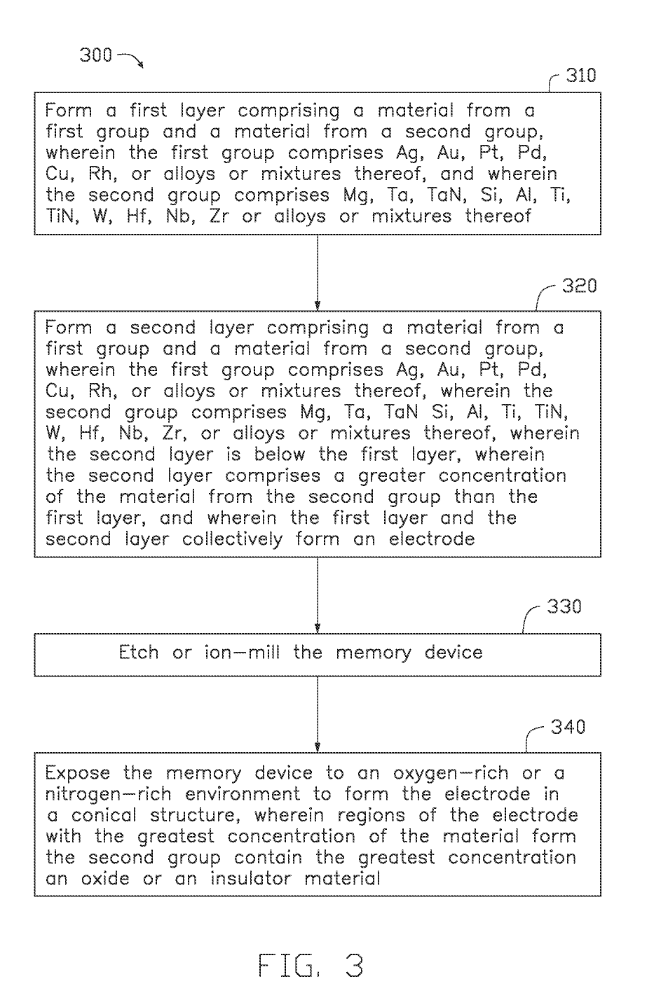

FIG. 3 schematically illustrates operations of a method 300 for forming a memory device, according to one embodiment described herein. At operation 310 a first layer may be formed. The first layer may comprise a material from a first group and a material from a second group. The first group may comprise Ag, Au, Pt, Pd, Cu, Rh, or alloys or mixtures thereof. The second group may comprise Mg, Ta, TaN, Si, Al, Ti, TiN, W, Hf, Nb, Zr, or alloys or mixtures thereof.

At operation 320 a second layer may be formed. The second layer may comprise a material from a first group and a material from a second group. The first group may comprise Ag, Au, Pt, Pd, Cu, Rh, or alloys or mixtures thereof. The second group may comprise Mg, Ta, TaN, Si, Al, Ti, TiN, W, Hf, Nb, Zr, or alloys or mixtures thereof. The second layer may be below the first layer. The second layer may comprise a greater concentration of the material from the second group than the first layer. The first layer and the second layer may collectively form and electrode.

At operation 330 the memory device may be etched or ion-milled. At operation 340 the memory device may be exposed to an oxygen-rich or a nitrogen-rich environment to form the electrode in a conical structure. The regions of the electrode with the greatest concentration of the material from the second group may contain the greatest concentration of an oxide or an insulator material.

In some embodiments, the method 300 may also include forming a third layer. The third layer may comprise a material from a first group and a material from a second group, wherein the first group comprises Ag, Au, Pt, Pd, Cu, Rh, or alloys or mixtures thereof, and wherein the second group comprises Mg, Ta, TaN, Si, Al, Ti, TiN, W, Hf, Nb, Zr, or alloys or mixtures thereof. The method 300 may further include forming a fourth layer comprising a material from a first group and a material from a second group. The first group may comprise Ag, Au, Pt, Pd, Cu, Rh, or alloys or mixtures thereof, and the second group may comprise Mg, Ta, TaN, Si, Al, Ti, TiN, W, Hf, Nb, Zr, or alloys or mixtures thereof. The fourth layer may be below the third layer. The third layer may comprise a greater concentration of the material from the second group than the fourth layer. The third layer and the fourth layer may collectively form a second electrode. The second electrode may be formed prior to the exposing of the first electrode to an oxygen-rich or a nitrogen-rich environment. The method 300, in some embodiments, may also include exposing the second electrode to an oxygen-rich or a nitrogen-rich environment to form the second electrode in a conical structure. Regions of the second electrode with the greatest concentration of the material from the second group contain the greatest concentration of an oxide or an insulator material. In certain embodiments, the exposing of the first electrode and the second electrode to the oxygen-rich or the nitrogen-rich environment may occur at the same time.

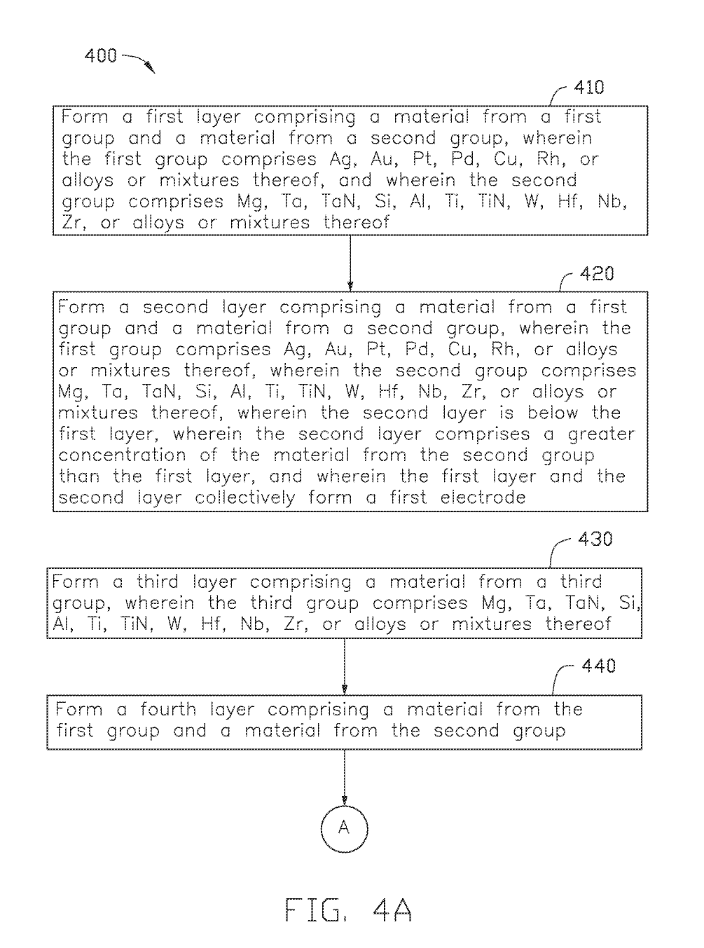

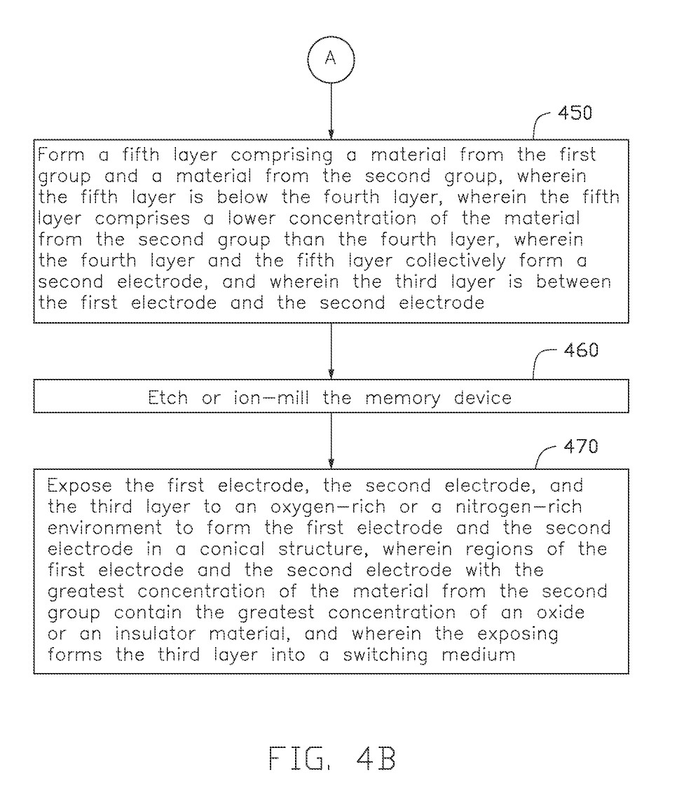

FIGS. 4A and 4B schematically illustrate operations of a method 400 for forming a memory device, according to one embodiment described herein. At operation 410, a first layer may be formed. The first layer may comprise a material from a first group and a material from a second group. The first group may comprise Ag, Au, Pt, Pd, Cu, Rh, or alloys or mixtures thereof. The second group may comprise Mg, Ta, TaN, Si, Al, Ti, TiN, W, Hf, Nb, Zr, or alloys or mixtures thereof.

At operation 420 a second layer may be formed. The second layer may comprise a material from a first group and a material from a second group. The first group may comprise Ag, Au, Pt, Pd, Cu, Rh, or alloys or mixtures thereof. The second group may comprise Mg, Ta, TaN, Si, Al, Ti, TiN, W, Hf, Nb, Zr, or alloys or mixtures thereof. The second layer may be below the first layer. The second layer may comprise a greater concentration of the material from the second group than the first layer. The first layer and the second layer may collectively form a first electrode.

At operation 430 a third layer may be formed. The third layer may comprise a material from a third group. The third group may comprise Mg, Ta, TaN, Si, Al, Ti, TiN, W, Hf, Nb, Zr, or alloys or mixtures thereof.

At operation 440 a fourth layer may be formed. The fourth layer may comprise a material from the first group and a material from the second group.

At operation 450 a fifth layer may be formed. The fifth layer may comprise a material from the first group and a material from the second group. The fifth layer may be below the fourth layer. The fifth layer may comprise a lower concentration of the material from the second group than the fourth layer. The fourth layer and the fifth layer may collectively form a second electrode. The third layer may be between the first electrode and the second electrode. In some embodiments, the first layer, the second layer, the fourth layer, and the fifth layer may each have a thickness of between about 0.05 nm and about 4 nm. In some embodiments, the first layer and the second layer may each have a different thickness, and/or the fourth layer and the fifth layer may each have a different thickness.

At operation 460 the memory device may be etched or ion-milled.

At operation 470, the first electrode, the second electrode, and the third layer may be exposed to an oxygen-rich or a nitrogen-rich environment. The exposing may form the first electrode and the second electrode in a conical structure. Regions of the first electrode and the second electrode with the greatest concentration of the material from the second group may contain the greatest concentration of an oxide or an insulator material. The exposing may form the third layer into a switching medium. In some embodiments, the oxide or insulator material may be formed on an outside edge of each of the first layer, the second layer, the fourth layer, and/or the fifth layer.

In some embodiments, the method 400 may further include combining the first layer and the second layer to form a first multilayer electrode structure. In some embodiments, the method 400 may further include combining the fourth layer and the fifth layer to form a second multilayer electrode structure. The first and/or second multilayer electrode structure may be a top electrode, a bottom electrode, and/or both the top electrode and the bottom electrode within the memory device.

In some embodiments, the method 400 may further include, forming a sixth layer. The sixth layer may include a material from the first group and a material from the second group.

In some embodiments, the method 400 may further include forming a seventh layer. The seventh layer may include a material from the first group and a material from the second group. The seventh layer may be below the sixth layer. The seventh layer may comprise a greater concentration of the material from the second group than the sixth layer. The sixth layer and the seventh layer may collectively form a third electrode.

In some embodiments, the method 400 may further include forming an eighth layer comprising a material from the third group. The method 400 may also include forming a ninth layer. The ninth layer may include a material from the first group and a material from the second group. The method 400 may also include forming a tenth layer. The tenth layer may comprise a material from the first group and a material from the second group. The tenth layer may be below the ninth layer. The tenth layer may comprise a lower concentration of the material from the second group than the ninth layer. The ninth layer and the tenth layer may collectively form a fourth electrode. The eighth layer may be between the third electrode and the fourth electrode. The third electrode and the fourth electrode may be formed prior to the exposing of the first electrode and the second electrode to an oxygen-rich or a nitrogen-rich environment.

In some embodiments, the method 400 may also include exposing the third electrode, the fourth electrode, and the eighth layer to an oxygen-rich or a nitrogen-rich environment to form the third electrode and the fourth electrode in a conical structure. Regions of the third electrode and the fourth electrode with the greatest concentration of the material from the second group may contain the greatest concentration of an oxide or an insulator material.

In some embodiments, the exposing of the first electrode, the second electrode, the third electrode, and the fourth electrode to the oxygen-rich or the nitrogen-rich environment may occur at the same time.

Benefits of the present disclosure include a ReRAM filamentary device with improved filament location predictability. As such, the filament location is controlled and filament formation near device edges is avoided. The formation of a filament near the point of the conical structure of pyramid-like structure may improve device yield, lower forming voltages necessary for filament formation, and improve reproducibility.

The present disclosure provides a materials stack and method for creating an improved filamentary ReRAM non-volatile memory cell by focusing the electric field at the center of the cell. By depositing a non-uniform metallic electrode, either compositionally modulated or multilayer, which is subsequently exposed to, for example, an oxidation process during cell fabrication, a metal electrode profile is automatically created which favors the center of the cell as the location with the highest electric field. For ReRAM cells in which filament creation/dissolution is the switching mechanism, for example OxRAM or CBRAM, the apparatus and method of the present disclosure increases the probability of filament formation near the center of the cell, which is favorable for size scaling and reliability of the non-volatile memory component.

While the foregoing is directed to embodiments of the present disclosure, other and further embodiments of the disclosure may be devised without departing from the basic scope thereof, and the scope thereof is determined by the claims that follow.

1. A resistive random access memory (ReRAM) device, comprising:
a multilayer metallic electrode structure, comprising a plurality of layers, wherein each layer of the plurality of layers comprises a first material selected from a first group and a second material selected from a second group, wherein the first group consists of Ag, Au, Pt, Pd, Cu, Rh, or alloys or mixtures thereof, and wherein the second group consists of Mg, Ta, TaN, Si, Al, Ti, TiN, W, Hf, Nb, Zr, or alloys or mixtures thereof; and
a switching medium, wherein a first layer of the plurality of layers that is closest to the switching medium comprises the greatest concentration of the second material of the second group, and wherein a second layer of the plurality of layers that is furthest away from the switching medium comprises the lowest concentration of the second material of the second group.

2. The resistive random access memory device of claim 1, wherein each layer of the plurality of layers has a thickness of between about 0.05 nm and about 4 nm.

3. The resistive random access memory device of claim 1, wherein each layer of the plurality of layers has a different thickness.

4. The resistive random access memory device of claim 1, wherein the plurality of layers comprises between two layers and ten layers.

5. The resistive random access memory device of claim 1, wherein the plurality of layers comprises more than ten layers.

6. The resistive random access memory device of claim 1, wherein the concentration of the second material of the second group of the second layer is zero percent.

7. The resistive random access memory device of claim 1, wherein the electrode structure is formed in a cone-shaped structure with an oxide or an insulator material formed on an outside edge of each layer.

8. The resistive random access memory device of claim 7, wherein the layer comprising the greatest concentration of the second material further comprises the greatest amount of oxide or insulator material.

9. The resistive random access memory device of claim 1, wherein the multilayer metallic electrode structure may be a top electrode, a bottom electrode, or both within the resistive random access memory device.

10. The resistive random access memory device of claim 1, further comprising a second electrode structure, wherein the multilayer metallic electrode structure is coupled with a first side of the switching medium and the second electrode structure is coupled with a second side of the switching medium opposite the first side.

11. The resistive random access memory device of claim 10, wherein the second electrode structure is a second multilayer metallic electrode structure, comprising a second plurality of layers, wherein each layer of the second plurality of layers comprises a first material selected from a first group and a second material selected from a second group, wherein the first group consists of Ag, Au, Pt, Pd, Cu, Rh, or alloys or mixtures thereof, wherein the second group consists of Mg, Ta, TaN, Si, Al, Ti, TiN, W, Hf, Nb, Zr, or alloys or mixtures thereof, and wherein a first layer of the second plurality of layers that is closest to the switching medium comprises the greatest concentration of the second material of the second group, and wherein a second layer of the second plurality of layers that is furthest away from the switching medium comprises the lowest concentration of the first material of the second group.

12. A memory device, comprising:
at least one layer, comprising one of an element of a first group and one of an element of a second group, wherein the first group is selected from the group consisting of Ag, Au, Pt, Pd, Cu, Rh, or alloys or mixtures thereof, and wherein the second group is selected from the group consisting of Mg, Ta, TaN, Si, Al, Ti, TiN, W, Hf, Nb, Zr, or alloys or mixtures thereof;
a switching medium, wherein the concentration of the element of the first group is varied continuously and the concentration of the element of the second group is varied continuously, wherein the concentration of the element of the second group is greatest near the switching medium and the concentration of the element of the first group is greatest away from the switching medium; and
a contact, wherein the layer is located between the switching medium and the contact.

13. The memory device of claim 12, wherein the layer has a thickness of between about 0.05 nm and about 4 nm.

14. The memory device of claim 12, wherein the concentration of the element of the second group is zero percent at a location on the at least one layer furthest from switching medium.

15. The memory device of claim 12, wherein the electrode structure is formed in a cone-shaped structure with an oxide or an insulator material formed on an outside edge of the layer.

16. A method for forming a memory device, comprising:
forming a first layer comprising a material from a first group and a material from a second group, wherein the first group comprises Ag, Au, Pt, Pd, Cu, Rh, or alloys or mixtures thereof, and wherein the second group comprises Mg, Ta, TaN, Si, Al, Ti, TiN, W, Hf, Nb, Zr, or alloys or mixtures thereof;
forming a second layer comprising a material from a first group and a material from a second group, wherein the first group comprises Ag, Au, Pt, Pd, Cu, Rh, or alloys or mixtures thereof, wherein the second group comprises Mg, Ta, TaN, Si, Al, Ti, TiN, W, Hf, Nb, Zr, or alloys or mixtures thereof, wherein the second layer is below the first layer, wherein the second layer comprises a greater concentration of the material from the second group than the first layer, and wherein the first layer and the second layer collectively form a first electrode;
etching or ion-milling the memory device; and
exposing the first electrode to an oxygen-rich or a nitrogen-rich environment to form the first electrode in a conical structure, wherein regions of the first electrode with the greatest concentration of the material from the second group contain the greatest concentration of an oxide or an insulator material.

17. The method of claim 16, wherein the first layer and the second layer each have a thickness of between about 0.05 nm and about 4 nm.

18. The method of claim 16, wherein first layer and the second layer each have a different thickness.

19. The method of claim 16, wherein the oxide or insulator material is formed on an outside edge of each of the first layer and the second layer.

20. The method of claim 16, further comprising combining the first layer and the second layer to form a multilayer electrode structure, and wherein the multilayer electrode structure may be a top electrode, a bottom electrode, or both within the memory device.

21. The method of claim 16, further comprising:
forming a third layer comprising a material from a first group and a material from a second group, wherein the first group comprises Ag, Au, Pt, Pd, Cu, Rh, or alloys or mixtures thereof, and wherein the second group comprises Mg, Ta, TaN, Si, Al, Ti, TiN, W, Hf, Nb, Zr, or alloys or mixtures thereof;
forming a fourth layer comprising a material from a first group and a material from a second group, wherein the first group comprises Ag, Au, Pt, Pd, Cu, Rh, or alloys or mixtures thereof, wherein the second group comprises Mg, Ta, TaN, Si, Al, Ti, TiN, W, Hf, Nb, Zr, or alloys or mixtures thereof, wherein the fourth layer is below the third layer, wherein the third layer comprises a greater concentration of the material from the second group than the fourth layer, and wherein the third layer and the fourth layer collectively form a second electrode, and wherein the second electrode is formed prior to the exposing of the first electrode to an oxygen-rich or a nitrogen-rich environment; and
exposing the second electrode to an oxygen-rich or a nitrogen-rich environment to form the second electrode in a conical structure, wherein regions of the second electrode with the greatest concentration of the material from the second group contain the greatest concentration of an oxide or an insulator material.

22. The method of claim 21, wherein the exposing of the first electrode and the second electrode to the oxygen-rich or the nitrogen-rich environment occurs at the same time.

23. A method for forming a memory device, comprising:
forming a first layer comprising a material from a first group and a material from a second group, wherein the first group comprises Ag, Au, Pt, Pd, Cu, Rh, or alloys or mixtures thereof, and wherein the second group comprises Mg, Ta, TaN, Si, Al, Ti, TiN, W, Hf, Nb, Zr, or alloys or mixtures thereof;
forming a second layer comprising a material from a first group and a material from a second group, wherein the first group comprises Ag, Au, Pt, Pd, Cu, Rh, or alloys or mixtures thereof, wherein the second group comprises Mg, Ta, TaN, Si, Al, Ti, TiN, W, Hf, Nb, Zr, or alloys or mixtures thereof, wherein the second layer is below the first layer, wherein the second layer comprises a greater concentration of the material from the second group than the first layer, and wherein the first layer and the second layer collectively form a first electrode;
forming a third layer comprising a material from a third group, wherein the third group comprises Mg, Ta, TaN, Si, Al, Ti, TiN, W, Hf, Nb, Zr, or alloys or mixtures thereof;
forming a fourth layer comprising a material from the first group and a material from the second group;
forming a fifth layer comprising a material from the first group and a material from the second group, wherein the fifth layer is below the fourth layer, wherein the fifth layer comprises a lower concentration of the material from the second group than the fourth layer, wherein the fourth layer and the fifth layer collectively form a second electrode, and wherein the third layer is between the first electrode and the second electrode;
etching or ion-milling the memory device; and
exposing the first electrode, the second electrode, and the third layer to an oxygen-rich or a nitrogen-rich environment to form the first electrode and the second electrode in a conical structure, wherein regions of the first electrode and the second electrode with the greatest concentration of the material from the second group contain the greatest concentration of an oxide or an insulator material, and wherein the exposing forms the third layer into a switching medium.

24. The method of claim 23, wherein the first layer, the second layer, the fourth layer, and the fifth layer each have a thickness of between about 0.05 nm and about 4 nm.

25. The method of claim 23, wherein first layer and the second layer each have a different thickness.

26. The method of claim 23, wherein the fourth layer and the fifth layer each have a different thickness.

27. The method of claim 23, wherein the oxide or insulator material is formed on an outside edge of each of the first layer, the second layer, the fourth layer, and the fifth layer.

28. The method of claim 23, further comprising combining the first layer and the second layer to form a multilayer electrode structure, and wherein the multilayer electrode structure may be a top electrode, a bottom electrode, or both within the memory device.

29. The method of claim 23, further comprising combining the fourth layer and the fifth layer to form a multilayer electrode structure, and wherein the multilayer electrode structure may be a top electrode, a bottom electrode, or both within the memory device.

30. The method of claim 23, further comprising:
forming a sixth layer comprising a material from the first group and a material from the second group;
forming a seventh layer comprising a material from the first group and a material from the second group, wherein the seventh layer is below the sixth layer, wherein the seventh layer comprises a greater concentration of the material from the second group than the sixth layer, and wherein the sixth layer and the seventh layer collectively form a third electrode;
forming an eighth layer comprising a material from the third group;
forming a ninth layer comprising a material from the first group and a material from the second group;
forming a tenth layer comprising a material from the first group and a material from the second group, wherein the tenth layer is below the ninth layer, wherein the tenth layer comprises a lower concentration of the material from the second group than the ninth layer, wherein the ninth layer and the tenth layer collectively form a fourth electrode, wherein the eighth layer is between the third electrode and the fourth electrode, and wherein the third electrode and the fourth electrode are formed prior to the exposing of the first electrode and the second electrode to an oxygen-rich or a nitrogen-rich environment; and
exposing the third electrode, the fourth electrode, and the eighth layer to an oxygen-rich or a nitrogen-rich environment to form the third electrode and the fourth electrode in a conical structure, wherein regions of the third electrode and the fourth electrode with the greatest concentration of the material from the second group contain the greatest concentration of an oxide or an insulator material.

31. The method of claim 30, wherein the exposing of the first electrode, the second electrode, the third electrode, and the fourth electrode to the oxygen-rich or the nitrogen-rich environment occurs at the same time.
